(19) United States
(12) Patent Application Publication
(10) Pub. No.: US 2026/0362663 A1
(43) Pub. Date: Nov. 12, 2026

(54) BATTERY HOUSING COMPONENT, TRACTION BATTERY HOUSING, TRACTION BATTERY AND MOTOR VEHICLE WITH TRACTION BATTERY

(71) Applicant: KAUTEX TEXTRON GmbH & Co. KG, Bonn (DE)

(72) Inventors: Nicolai SCHUMACHER, Bonn (DE); Marin DAUBEN, Much (DE); Maria ENGLBRECHT, Aufhausen (DE)

(73) Assignee: KAUTEX TEXTRON GmbH & Co. KG, Bonn (DE)

(21) Appl. No.: 19/469,934

(22) PCT Filed: Mar. 13, 2024
(86) PCT No.: PCT/EP2024/056645

§ 371 Date: Sep. 26, 2025

(30) Foreign Application Priority Data
Mar. 31, 2023 (DE) 10 2023 108 315.5

(51) Int. Cl. H05K 9/00; H01M 10/658; H01M 50/224; H01M 50/227; H01M 50/231; H01M 50/233; H01M 50/249

(52) U.S. Cl. CPC H05K 9/0086; H01M 10/658; H01M 50/224; H01M 50/227; H01M 50/231; H01M 50/233; H01M 50/249

(57) ABSTRACT

The present invention relates to a battery housing component for a traction battery housing which is designed to accommodate at least one battery component, wherein the battery housing component comprises an outer layer comprising a plastic and at least one shielding layer comprising a metal, wherein the shielding layer covers substantially an entire inner surface of the outer layer, and wherein the shielding layer is form-fittingly connected to the outer layer. Furthermore, the present invention relates to a traction battery housing comprising at least one battery housing component, a traction battery comprising a traction battery housing and a motor vehicle comprising a traction battery.

The present invention relates to a battery housing component for a traction battery housing. Furthermore, the present invention relates to a traction battery housing for accommodating at least one battery component. Furthermore, the present invention relates to a traction battery for a motor vehicle and a motor vehicle with a traction battery.

Traction batteries for motor vehicles generally have a traction battery housing made of metal. Correspondingly designed traction battery housings also function as a Faraday cage, so that electromagnetic radiation is neither emitted from a receiving volume of the traction battery housing to the outside world nor does electromagnetic radiation from the outside world penetrate into the interior of the traction battery housing. The disadvantage of such traction battery housings is their high weight and their inadequate properties as a heat barrier. For example, heat that is released in the battery housing volume when battery cells or battery modules thermally pass through is also released to a very large extent into the environment and thus also in the direction of a passenger compartment, which means that the risk of injury to passengers in a motor vehicle with a correspondingly designed traction battery housing is very high. In addition, heat generated, for example, in the event of a vehicle fire or other fire, is also transferred to a large extent into the storage volume of a correspondingly designed traction battery housing, so that battery components arranged in the traction battery housing can be damaged.

Traction battery housings made of plastic have a significantly reduced dead weight and are at least equal if not superior to traction battery housings made of aluminum in terms of their structural integrity. However, traction battery housings made of plastic have the disadvantage that they provide poor protection against the effects of penetrating electromagnetic radiation for battery components located in a receiving volume of the traction battery housing. Furthermore, electromagnetic radiation generated by battery components located in the receiving volume is emitted to the outside world essentially unfiltered.

To solve this problem, it is known from the state of the art to provide an outer surface of a traction battery housing made of plastic with an aluminum layer. However, a correspondingly designed traction battery housing has the disadvantage that the aluminum layer is exposed to chemical and physical environmental influences and is therefore not stable over the long term.

The present invention is based on the task of providing a battery housing component for a traction battery housing which has a low weight and an improved and long-term stable insulating effect for electromagnetic radiation.

The task underlying the present invention is solved by a battery housing component with the features of claim 1 of the present invention. Advantageous embodiments of the battery housing component are described in the claims dependent on claim 1.

More specifically, the problem underlying the present invention is solved by a battery housing component for a traction battery housing which is designed to accommodate at least one battery component, wherein the battery housing component comprises an outer layer comprising a plastic and at least one shielding layer comprising a metal, wherein the shielding layer covers substantially an entire inner surface of the outer layer, and wherein the shielding layer is form-fittingly connected to the outer layer.

The battery housing component according to the invention has the advantage that, despite its low weight, it has an excellent and long-term stable protective effect against the penetration of electromagnetic radiation into a traction battery housing comprising the battery housing component according to the invention. Furthermore, the battery housing component according to the invention has the advantage that, despite its low weight, it has an excellent and long-term stable protective effect against the leakage of electromagnetic radiation from a traction battery housing comprising the battery housing component according to the invention. Furthermore, the battery housing component according to the invention has the advantage that it has an improved thermal barrier effect.

The battery housing component is preferably designed as a battery housing shell or as a battery housing cover or as underbody protection.

The battery component is, for example, a battery cell or a battery module.

The outer layer forms an outer layer of the battery housing when the battery housing component is assembled, i.e. when the battery housing component is assembled in or to the battery housing.

In the assembled state of the battery housing component, i.e. when the battery housing component is assembled in or to the battery housing, the shielding layer faces a receiving volume of the battery housing.

The shielding layer is preferably formed from a metal. Preferably, the shielding layer is made of aluminum, iron or steel. There are no restrictions with regard to the choice of metal according to the invention.

According to the invention, the feature according to which the shielding layer covers substantially the entire inner surface of the outer layer means that an area enclosed by an outline surrounding the shielding layer covers substantially the entire inner surface of the outer layer. Consequently, according to the invention, the feature according to which the shielding layer covers substantially the entire inner surface of the outer layer also means that the shielding layer may have one or a plurality of through openings. Even if the shielding layer has one or a plurality of through openings, the feature is fulfilled that the shielding layer substantially or preferably completely covers the entire inner surface of the outer layer.

The shielding layer can be directly form-fittingly connected to the outer layer. This means that there is no need for an adhesive layer between the shielding layer and the outer layer.

The shielding layer can have a thickness extension in a range from 0.1 mm to 3 mm, preferably in a range from 0.5 mm to 2 mm and more preferably in a range from 0.2 mm to 0.5 mm. This means that the shielding layer can be manufactured with a reduced amount of material and thus with a reduced weight.

The plastic of the outer layer can be a polypropylene (PP), a polyamide (PA), a fiber-plastic compound (SMC; abbreviation for sheet molding compound), a glass fiber-reinforced PA and/or a glass fiber-reinforced PP. According to the invention, there are no restrictions with regard to the choice of plastic.

Preferably, the battery housing component is designed such that the shielding layer has a plurality of through-openings, with material of the outer layer extending at least partially into the through-openings of the shielding layer.

A battery housing component designed in this way has the advantage that the shielding layer is connected to the outer layer in an improved and simplified form-fitting manner.

The through openings can each have a free cross-sectional area of less than or equal to an area corresponding to a circular area with a diameter of between 0.1 mm and 45 mm. Preferably, the through openings can each have a free cross-sectional area of less than or equal to an area corresponding to a circular area with a diameter of 10 mm, preferably a circular area with a diameter of 8 mm. This allows a good electromagnetic shielding effect of the shielding layer to be achieved while at the same time using less material for the shielding layer.

The cross-sectional areas of the through-openings can, for example, be designed as an ellipse or an oval or a rhombus or a rectangle or a square.

Preferably, the cross-sectional areas of the through-openings are circular. This allows an improved electromagnetic shielding effect of the shielding layer to be achieved while using even less material for the shielding layer. Since a circle has the smallest ratio of circumference to surface area compared to other geometric shapes, even more material can be saved in the shielding layer without negatively influencing the electromagnetic shielding effect.

Preferably, the battery housing component is designed in such a way that the material of the outer layer protrudes through the through-openings and engages behind the through-openings.

A battery housing component designed in this way has the advantage that the shielding layer is connected to the outer layer with an even better form fit. The fact that material from the outer layer protrudes through and engages behind the through openings means that a riveted connection can be formed between the outer layer and the shielding layer.

Preferably, the battery housing component is designed in such a way that the through-openings each have a conical cross-sectional shape over at least part of their respective longitudinal extensions, the respective free diameters of the through-openings increasing from a contact surface of the shielding layer, which is in contact with the inner surface of the outer layer, towards a surface of the shielding layer opposite the contact surface.

A battery housing component designed in this way has the advantage that the shielding layer is connected to the outer layer with an even better form fit and can be manufactured more easily at the same time. The fact that a form fit connection can be achieved without the material of the outer layer having to protrude through and engage behind the through openings means that the shielding layer can be positioned more easily, for example as an insert in a manufacturing process.

Preferably, the battery housing component is designed in such a way that the shielding layer is designed as a grid, preferably as an expanded metal grid.

A battery housing component designed in this way has the advantage that the shielding layer can be produced with even less material, so that the battery housing component has an even lower weight. In addition, the shaping of the shielding layer is considerably simplified.

Preferably, the battery housing component is designed in such a way that the battery housing component has a thermal insulation layer that is connected to the shielding layer, and the shielding layer is sandwiched between the outer layer and the thermal insulation layer.

A battery housing component designed in this way has the advantage that the battery housing component has an improved thermal insulation effect.

The thermal insulation layer is preferably designed as a thermal protection fleece. However, the present invention is not limited to a corresponding design of the thermal insulation layer. The thermal insulation layer may also consist of or comprise a knitted fabric, a woven fabric or the like.

The thermal insulation layer can be connected to the shielding layer by a material bond and/or a form-fit and/or a force-fit. In particular, the thermal insulation layer can be connected to the shielding layer by means of rivets, staples, screws or other connecting means.

Preferably, the battery housing component is designed in such a way that the battery housing component has a metal protective layer which is connected to the thermal insulation layer, and the thermal insulation layer is sandwiched between the shielding layer and the metal protective layer.

A battery housing component designed in this way has the advantage that the battery housing component has a further improved electromagnetic shielding effect and at the same time has an improved protective effect against mechanical effects on the battery housing component. Furthermore, the battery housing component designed in this way has the advantage that the battery housing component has further improved resistance to high temperatures, which occur, for example, when battery cells are thermally run through.

The protective metal layer is preferably made of aluminum, iron, steel or stainless steel. There are no restrictions with regard to the choice of metal according to the invention.

The metal protective layer preferably has a thickness of less than or equal to 0.25 mm, preferably less than or equal to 0.15 mm. As a result, the weight of the battery housing component can be further reduced while at the same time increasing the electromagnetic shielding effect and protection against mechanical impact.

The metal protective layer can be bonded to the thermal insulation layer in a material-fit and/or form-fit and/or force-fit manner. In particular, the metal protective layer can be connected to the thermal insulation layer using rivets, staples, screws or other connecting means.

Preferably, the battery housing component is designed such that the battery housing component has a plastic protective layer that is connected to the metal protective layer, an the metal protective layer is sandwiched between the thermal insulation layer and the plastic protective layer.

A battery housing component designed in this way has the advantage that an electrical insulation layer is formed between the metal protective layer and electrical components (e.g. high-voltage cables, high-voltage connections, battery cells) in the interior of a traction battery housing which has a battery housing component designed in this way. Furthermore, a battery housing component formed in this way has the advantage that the battery housing component has an improved protective effect against chemical effects, in particular against corrosion, by components of battery components arranged in a receiving volume.

The plastic protective layer preferably comprises a polypropylene (PP), a polyethylene (PE), an ethylene vinyl acetate (EVA), a polyamide (PA), a polyethylene terephthalate (PET) and/or a thermoplastic polyurethane (TPU).

The plastic protective layer can be bonded to the metal protective layer in a material-locking and/or form-fitting and/or force-locking manner. In particular, the plastic protective layer can be connected to the metal protective layer by means of rivets, staples, screws or other connecting means. Furthermore, the plastic protective layer can be connected to the metal protective layer by means of adhesion promoters, in particular thermally activatable adhesion promoters, or by means of bonding.

The outer layer, the shielding layer, the thermal insulation layer, the metal protective layer and the plastic protective layer can be joined together using rivets, staples, screws or other joining means and form a one-piece component. The one-piece component formed in this way can have a thickness of less than or equal to 3 mm, preferably less than or equal to 2 mm.

Preferably, the battery housing component is designed in such a way that it has an edge-side connecting device, which is preferably designed as a connecting flange and which is designed for connection to a further battery housing component.

A battery housing component designed in this way has the advantage that the battery housing component can be connected to another battery housing component in a simplified manner.

The connecting device is preferably designed as a continuous connecting device that runs circumferentially around the edges of a receiving volume that is at least partially limited by the battery housing component.

The connecting device can have a receiving recess, whereby the receiving recess is designed to receive at least one sealing device.

The receiving recess can be designed as a continuous receiving recess surrounding the receiving volume that is at least partially limited by the battery housing component.

The recess has a smaller depth extension than the thickness extension of the at least one shielding layer. As a result, an improved mechanical connection between two battery housing components and a sealing device can be achieved by increasing the compression of the sealing device.

The sealing device can be arranged in the receiving recess. As a result, improved positioning accuracy of the sealing device in the battery housing component can be achieved.

The sealing device can be designed as a continuous sealing device that surrounds at least part of the receiving volume limited by the battery housing component. This can improve the sealing of the receiving volume.

The connecting device preferably has at least one elevation. This can improve direct contact between a shielding layer covering the connecting device and a surface opposite this shielding layer. In particular, the opposite surface can be designed as a further shielding layer of a further battery housing component covering a connecting device. This can improve electrically conductive contact between the two shielding layers.

Preferably, the battery housing component is designed in such a way that the connecting device is formed integrally and/or monolithically with the outer layer, and the shielding layer covers at least part of the connecting device.

A battery housing component designed in this way has the advantage that the outer layer and thus the battery housing component can be manufactured in a simplified manner, in particular in a single manufacturing step.

Two monolithically connected elements are made from one piece. In particular, two monolithically interconnected elements are joined together seamlessly.

The present invention is also based on the task of providing a traction battery housing for a traction battery, which has a low weight and an improved and long-term stable insulating effect for electromagnetic radiation.

This task on which the present invention is based is solved by a traction battery housing for accommodating at least one battery component with the features of claim 11. Advantageous embodiments are described in the claims dependent on claim 11.

More specifically, the problem underlying the present invention is solved by a traction battery housing for accommodating at least one battery component, wherein the traction battery housing has at least one battery housing component described above.

A traction battery housing designed in this way has the advantage that it has a low weight and at the same time an excellent and long-term stable protective effect against the penetration of electromagnetic radiation into the traction battery housing. Furthermore, a traction battery housing designed in this way has the advantage that it has a low weight and at the same time an excellent and long-term stable protective effect against electromagnetic radiation escaping from the traction battery housing. Furthermore, the traction battery housing according to the invention has the advantage that it has an improved thermal barrier effect.

The traction battery housing can have a housing component that is formed from a metal or has a metal. According to the invention, there are no restrictions with regard to the choice of metal material.

The housing component is preferably connected to the battery housing component in such a way that the housing component is directly or indirectly electrically conductively connected to the shielding layer of the battery housing component. A traction battery housing designed in this way has the advantage that an electrically conductive cage is formed which limits a holding volume and improves the electromagnetic shielding effect of the traction battery housing.

Preferably, the traction battery housing is designed in such a way that the traction battery housing has two battery housing components as described above, which are connected to each other and form a receiving volume for receiving the at least one battery component.

A traction battery housing designed in this way has the advantage that it has an even lower weight and at the same time an excellent and long-term stable protective effect against the penetration of electromagnetic radiation into the traction battery housing. Furthermore, a traction battery housing designed in this way has the advantage that it is even lighter and at the same time provides excellent and long-term stable protection against electromagnetic radiation escaping from the traction battery housing.

Preferably, the traction battery housing is designed in such a way that the traction battery housing has two battery housing components, each of which has the following features:
the battery housing component has an edge-side connecting device, which is preferably designed as a connecting flange and which is designed for connection to a further battery housing component;
the connecting device is formed integrally and/or monolithically with the outer layer; and
the shielding layer covers at least part of the connecting device.

The two battery housing components are connected to one another in such a way that their respective connecting devices are connected to one another and the shielding layers covering the respective connecting devices are arranged opposite one another. A traction battery housing designed in this way has the advantage that it can be manufactured in a simplified manner, while at the same time ensuring that the accommodation volume or the accommodation space of the correspondingly designed traction battery housing provides excellent protection against the penetration of electromagnetic radiation into the accommodation volume and against the emission of electromagnetic radiation from the accommodation volume to the environment of the traction battery housing. Furthermore, an appropriately designed traction battery housing makes it possible to maximize the volume for accommodating battery components.

Preferably, the traction battery housing is designed such that the traction battery housing has at least one sealing device which is arranged between the connecting devices of the two battery housing components, the two battery housing components are connected to one another by means of a plurality of connecting elements which each project through the connecting devices and force them towards one another. In a cross-section through the traction battery housing and the interconnected connecting devices, the at least one sealing device is arranged between a connecting element and the shielding layers arranged opposite to one another.

A traction battery housing designed in this way has the advantage that an improved connection is achieved between the two battery housing components, so that an improved sealing effect is achieved.

The two battery housing components can be connected to each other in such a way that their respective connecting devices are connected to each other and the shielding layers covering the respective connecting devices are arranged opposite each other and the respective receiving recesses are arranged opposite each other. A traction battery housing designed in this way has the advantage that a sealing device can be arranged in an improved manner between the two connecting devices, so that a further increased sealing effect is achieved.

The sealing device can be made of plastic.

The cross-sectional area of the sealing device in the plane of the cross-section through the traction battery housing and the interconnected connecting devices can have a semi-circular shape or a circular shape or a rectangular shape or a square shape or a double-circular shape. A double circle shape can be understood as a shape of a figure eight lying on its side. In other words, a double circular shape may comprise two circular shapes which are arranged side by side in the plane of the cross-section through the traction battery housing and the interconnected connecting devices and are connected to each other, in particular are monolithically connected to each other. Each of the circular shapes can be designed as a sealing device portion. In other words, a sealing device comprising a double circular shape can have at least two sealing device portion.

The connecting elements may be formed as screws, rivets, bolts or other connecting elements, preferably electrically conductive ones.

Preferably, the traction battery housing is designed in such a way that the shielding layers covering the respective connecting devices are in direct contact with each other.

A traction battery housing designed in this way has the advantage that the traction battery housing has an improved shielding effect for electromagnetic radiation. At the same time, an appropriately designed traction battery housing has improved mechanical stability, as the shielding layers of the respective connecting devices are in direct contact with each other.

Preferably, the shielding layers partially covering the respective connecting devices are in direct surface contact with each other. A traction battery housing designed in this way has the advantage that an improved electrically conductive contact is achieved between the respective shielding layers.

The respective connecting devices of the battery housing shells can each have at least one elevation. This can improve the direct contact between the respective shielding layers.

Preferably, the traction battery housing is designed such that the shielding layers covering the respective connecting devices are spaced apart from one another, wherein the at least one sealing device has a sealing device portion which is electrically conductive, and wherein the shielding layers covering the respective connecting devices are in direct electrical contact with the sealing device portion.

A traction battery housing designed in this way has the advantage that the traction battery housing has an improved insulating effect for electromagnetic radiation and at the same time can be subjected to a defined force applied by the plurality of connecting elements.

The electrically conductive sealing device portion can be formed as a metal mesh arranged around a portion of the sealing device.

The present invention is also based on the task of providing a traction battery for a motor vehicle which has a low weight and an improved and long-term stable insulating effect for electro-magnetic radiation.

This task underlying the present invention is solved by a traction battery for a motor vehicle with the features of claim 17.

More specifically, the problem underlying the present invention is solved by a traction battery for a motor vehicle, wherein the traction battery has a traction battery housing described above and at least one battery component which is arranged in a receiving volume of the traction battery housing.

The present invention is also based on the task of providing a motor vehicle having a traction battery which has a low weight and an improved and long-term stable insulating effect for electromagnetic radiation.

This task underlying the present invention is solved by a motor vehicle having a traction battery with the features of claim 18.

Further advantages, details and features of the invention are shown below in the embodiment examples explained. These show in detail:

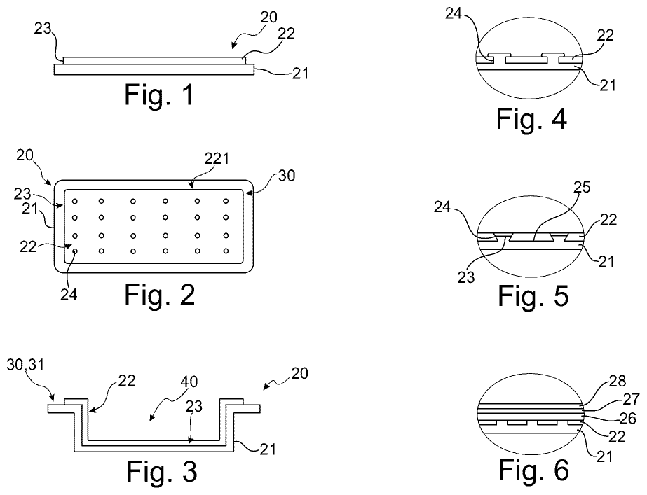

FIG. 1: a Schematic Cross-sectional Representation of a battery housing component according to the invention in accordance with a first embodiment of the present invention;

FIG. 2: a schematic top view of a battery housing component according to a second embodiment;

FIG. 3: a schematic cross-sectional view of a battery housing component according to a third embodiment;

FIG. 4: a schematic cross-sectional view of a connection area of a battery housing component according to a fourth embodiment;

FIG. 5: a schematic cross-sectional view of a connection area of a battery housing component according to a fifth embodiment;

FIG. 6: a schematic cross-sectional view of a battery housing component according to a sixth embodiment;

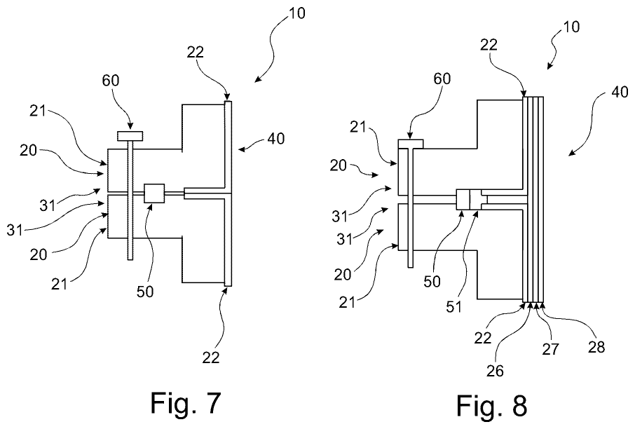

FIG. 7: a schematic cross-sectional view of a traction battery housing in the area of the connecting devices of the traction battery housing according to a seventh embodiment, and

FIG. 8: a schematic cross-sectional representation of a traction battery housing in the region of the connecting devices of the traction battery housing according to an eighth embodiment.

In the following description, the same reference signs denote the same components or the same features, so that a description carried out in relation to one figure with regard to a component also applies to the other figures, so that a repetitive description is avoided. Furthermore, individual features described in connection with one embodiment can also be used separately in other embodiments.

FIG. 1 shows a battery housing component 20 according to a first embodiment in a cross-sectional view. The battery housing component 20 is designed as a battery housing cover 20. The battery housing component 20 has an outer layer 21 comprising a plastic and a shielding layer 22 comprising a metal, wherein the shielding layer 22 covers substantially an entire inner surface 23 of the outer layer 21. The shielding layer 22 is form-fittingly connected to the outer layer 21.

FIG. 2 shows a battery housing component 20 according to a second embodiment in a plan view. The battery housing component 20 is designed as a battery housing cover 20. The shielding layer 22 has a plurality of through openings 24. In the embodiment shown, the through openings 24 have a circular cross-section, whereby according to the invention there are no restrictions with regard to the shape of the through-openings 24.

The shielding layer 22 covers substantially the entire inner surface 23 of the outer layer 21. In other words, the shielding layer 22 covers a surface of the outer layer 21 which is enclosed by an outline 221 surrounding the shielding layer 22.

The battery housing component 20 also has an edge-side connecting device 30, which is designed for connection to a further battery housing component 20.

FIG. 3 shows a battery housing component 20 according to a third embodiment in a schematic cross-sectional view. The battery housing component 20 is designed as a battery housing shell 20. The connecting device 30 is designed as a connecting flange 31. Furthermore, the connecting flange 31 is formed monolithically with the outer layer 21 and the shielding layer 22 covers at least a part of the connecting flange 31.

The connecting flange 31 is designed as a continuous connecting flange 31 running around the edge of a receiving volume 40. The battery housing component 20 at least partially delimits the receiving volume 40 of the battery housing component 20.

FIG. 4 shows a schematic cross-sectional view of a connection area of a battery housing component 20 according to of a fourth embodiment. In the connection area, the shielding layer 22 and the outer layer 21 are connected to each other.

The material of the outer layer 21 protrudes through the through openings 24 of the shielding layer 22 and engages behind the through openings 24 of the shielding layer 22, in that the material of the outer layer 21 spreads out again behind the through openings 24. This creates riveted joints by means of which the outer layer 21 and the shielding layer 22 are connected to each other.

FIG. 5 shows a schematic cross-sectional view of a battery housing component 20 according to a fifth embodiment in a connection area in which the shielding layer 22 is connected to the outer layer 21.

The material of the outer layer 21 extends at least partially into the through openings 24 of the shielding layer 22. The through openings 24 of the shielding layer 21 each have a conical cross-sectional shape over at least part of their respective longitudinal extension, wherein the respective free diameters of the through openings 24 increase from a contact surface 25 of the shielding layer 22, which is in contact with the inner surface 23 of the outer layer 21, towards a surface of the shielding layer 22 opposite the contact surface 25. Thus, the material of the outer layer 21 located in the respective through openings 24 engages behind the shielding layer 22.

FIG. 6 shows a schematic cross-sectional view of a battery housing component 20 according to a sixth embodiment.

The battery housing component 20 has a thermal insulation layer 26, which is connected to the shielding layer 22. The shielding layer 22 is sandwiched between the outer layer 21 and the thermal insulation layer 26.

The battery housing component 20 also has a metal protective layer 27, which is connected to the thermal insulation layer 26. The thermal insulation layer 26 is sandwiched between the shielding layer 22 and the metal protective layer 27.

The battery housing component 20 also has a plastic protective layer 28, which is connected to the metal protective layer 27. The metal protective layer 27 is sandwiched between the thermal insulation layer 26 and the plastic protective layer 28.

The outer layer 21, the shielding layer 22, the thermal insulation layer 26, the metal protective layer 27 and the plastic protective layer 28 are formed together as a one-piece component.

FIG. 7 shows a schematic cross-sectional representation of a traction battery housing 10 according to a seventh embodiment of the present invention.

The traction battery housing 10 for receiving at least one battery component has two battery housing components 20, which are connected to one another and form a receiving volume 40 for receiving the at least one battery component. The battery housing components 20 are each designed as battery housing shells 20. Each battery housing shell 20 has a connecting device 30, which is designed as a connecting flange 31.

The two battery housing components 20 are connected to one another in such a way that their respective connecting flanges 31 are connected to one another and the shielding layers 22 covering the respective connecting flanges 31 are arranged opposite one another.

The traction battery housing 10 also has a sealing device 50, which is arranged between the connecting flanges 31 of the two battery housing components 20. The two battery housing components 20 are connected to each other by means of a plurality of connecting elements 60, the connecting elements 60 each projecting through the connecting flanges 31 of the battery housing components 20 and applying force to them towards each other. In the cross-sectional view of the traction battery housing 10 shown in FIG. 7, the sealing device 50 is arranged between a connecting element 60 and the shielding layers 22 arranged opposite to one another.

In the illustrated embodiment, the sealing device 50 has a square cross-section in the cross-section through the traction battery housing 10 and the interconnected connecting flanges 31. However, the present invention is not limited to a corresponding geometry of the sealing device 50. For example, the sealing device 50 may also have a circular cross-sectional geometry.

The shielding layers 22 covering the respective connecting flanges 31 are in direct contact with each other. The shielding layers 22 are thus directly electrically connected to each other.

FIG. 8 shows a schematic cross-sectional representation of a traction battery housing 10 according to an eighth embodiment. In the embodiment shown in FIG. 8, the connecting devices 30 of the respective battery housing components 20 are also designed as connecting flanges 31.

The shielding layers 22 covering the respective connecting flanges 31 are arranged at a distance from one another. The at least one sealing device 50 has a sealing device portion 51 that is electrically conductive. FIG. 8 shows that the shielding layers 22 covering the respective connecting flanges 31 are in direct electrical contact with the sealing device portion 51.

The respective battery housing components 20 each have a thermal insulation layer 26, a metal protective layer 27 and a plastic protective layer 28. The thermal insulation layers 26 are each connected to the shielding layers 22. The metal protective layers 27 are each connected to the thermal insulation layers 26 and the plastic protective layers 28 are each connected to the metal protective layers 27. The shielding layers 22 are each sandwiched between the outer layers 21 and the thermal insulation layers 26. The thermal insulation layers 26 are sandwiched between the shielding layers 22 and the metal protective layers 27. The metal protective layers 27 are sandwiched between the thermal insulation layers 26 and the plastic protective layers 28. The plastic protective layers 28 thus directly face the receiving volume 40 formed by the battery housing components 20.

### LIST OF REFERENCE NUMERALS

10 Traction battery housing
20 Battery housing component
21 Outer layer
22 Shielding layer
221 Outline (of the shielding layer)
23 Inner surface (of the outer layer)
24 Through openings
25 Contact surface (of the shielding layer)
26 Thermal insulation layer
27 Metal protective layer
28 Plastic protective layer
30 Connecting device
31 Connecting flange
40 Receiving volume
50 Sealing device
51 Sealing device portion
60 Connecting element

1. A battery housing component for a traction battery housing which is designed to accommodate at least one battery component, wherein the battery housing component comprises
an outer layer comprising a plastic and
at least one shielding layer comprising a metal,
wherein the shielding layer covers substantially an entire inner surface of the outer layer, and
wherein the shielding layer is form-fittingly connected to the outer layer.

2. The battery housing component according to claim 1, characterized by the following features:
the shielding layer has a plurality of through openings; and
material of the outer layer extends at least partially into the through openings of the shielding layer.

3. The battery housing component according to claim 2, characterized in that the material of the outer layer projects through the through-openings and engages behind the through-openings.

4. The battery housing component according to claim 2, characterized in that the through-openings each have a conical cross-sectional shape over at least part of their respective longitudinal extensions, the respective free diameters of the through-openings increasing from a contact surface of the shielding layer, which is in contact with the inner surface of the outer layer, towards a surface of the shielding layer opposite the contact surface.

5. The battery housing component according to claim 1, characterized in that the shielding layer is designed as a grid, preferably as an expanded metal grid.

6. The battery housing component according to claim 1, characterized by the following features:
the battery housing component has a thermal insulation layer connected to the shielding layer; and
the shielding layer is sandwiched between the outer layer and the thermal insulation layer.

7. The battery housing component according to claim 6, characterized by the following features:
the battery housing component has a metal protective layer which is connected to the thermal insulation layer; and
the thermal insulation layer is sandwiched between the shielding layer and the metal protective layer.

8. The battery housing component according to claim 7, characterized by the following features:
the battery housing component has a plastic protective layer which is connected to the metal protective layer; and
the metal protective layer is arranged in a sandwich-like manner between the thermal insulation layer and the plastic protective layer.

9. The battery housing component according to claim 1, characterized in that it has an edge-side connecting device, which is preferably designed as a connecting flange, and which is designed for connection to a further battery housing component.

10. The battery housing component according to claim 9, characterized by the following features:
the connecting device is formed integrally and/or monolithically with the outer layer; and
the shielding layer covers at least a part of the connecting device.

11. The traction battery housing for accommodating at least one battery component, comprising:
at least one battery housing component comprising:
an outer layer comprising a plastic and
at least one shielding layer comprising a metal,
wherein the shielding layer covers substantially an entire inner surface of the outer layer, and
wherein the shielding layer is form-fittingly connected to the outer layer.

12. The traction battery housing according to claim 11, characterized in that the traction battery housing comprises two battery housing components, respectively, which are connected to each other and form a receiving volume for receiving the at least one battery component.

13. The traction battery housing according to claim 11, characterized by the following features:
the traction battery housing has two battery housing components; and
the two battery housing components are connected to one another in such a way that their respective connecting devices are connected to one another and the shielding layers covering the respective connecting devices are arranged opposite to one another.

14. The traction battery housing according to claim 13, characterized by the following features:
the traction battery housing has at least one sealing device which is arranged between the connecting devices of the two battery housing components;
the two battery housing components are connected to one another by means of a plurality of connecting elements which each project through the connecting devices and force them towards one another; and
in a cross-section through the traction battery housing and the interconnected connecting devices, the at least one sealing device is arranged between a connecting element and the shielding layers arranged opposite to one another.

15. The traction battery housing according to claim 14, characterized in that the shielding layers covering the respective connecting devices are in direct contact with each other.

16. The traction battery housing according to claim 14, characterized by the following features:
the shielding layers covering the respective connecting devices are spaced apart from one another;
the at least one sealing device has a sealing device portion which is electrically conductive; and
the shielding layers covering the respective connecting devices are in direct electrical contact with the sealing device portion.

17. A traction battery for a motor vehicle, comprising a traction battery housing according to claim 11 and at least one battery component arranged in a receiving volume of the traction battery housing.

18. A motor vehicle, comprising a traction battery according to claim 17.
